(19) United States
(12) Patent Application Publication
(10) Pub. No.: US 2018/0269344 A1
(43) Pub. Date: Sep. 20, 2018

(54) SOLAR CELL MODULE

(71) Applicant: CSI CELLS CO., LTD., SUZHOU (CN)

(72) Inventors: SONGBO WAN, SUZHOU (CN); XUSHENG WANG, SUZHOU (CN); GUOQIANG XING, SUZHOU (CN)

(21) Appl. No.: 15/987,446

(22) Filed: May 23, 2018

Related U.S. Application Data
(63) Continuation-in-part of application No. PCT/CN2016/077563, filed on Mar. 28, 2016.

(30) Foreign Application Priority Data
Jul. 2, 2015 (CN) 201510381209.1
Feb. 17, 2016 (CN) 201610089428.7

(51) Int. Cl. H01L 31/05; H01L 31/02

(52) U.S. Cl. CPC H01L 31/0508; H01L 31/0201

(57) ABSTRACT

Provided is a solar cell module including at least one solar cell string each including a plurality of solar cells connected in series by conductive tapes. A length of the solar cell in a direction in which the plurality of solar cells are connected in series by the conductive tapes is less than or equal to 10 cm. A total width of the conductive tapes adopted by each solar cell is 0.1% to 3% of a width of the solar cell. A ratio of the total width of the conductive tapes to the length of the solar cell is 8000 mm to 3000 mm. A contradiction between a shading loss and a resistance loss of the conductive tapes is harmonized, the maximization of output power is realized.

### CROSS-REFERENCES TO RELATED APPLICATIONS

The application is a continuation-in-part application of International Application No. PCT/CN2016/077563, with an international filing date of Mar. 28, 2016, which is based upon and claims priority to Chinese Patent Application No. 201510381209.1, filed on Jul. 2, 2015, and to Chinese Patent Application No. 201610089428.7, filed on Feb. 17, 2016, the entire contents of all of which are incorporated herein by reference.

### FIELD OF TECHNOLOGY

The following relates to the field of solar cells, and particularly relates to a solar cell module.

### BACKGROUND

Conventional fossil fuel runs out day by day. Among various sustainable energy sources, solar energy is undoubtedly the cleanest, the most common and the most promising alternative energy source. Photovoltaic power generation is one of power generation technologies with the most sustainable development ideal features. Currently, in various solar cells, the silicon solar cell is one of the solar cells which is commercially promoted widely because silicon is abundant in earth crust and the silicon solar cell has excellent electrical performance and mechanical performance compared with other types of solar cells. In future development of photovoltaic technologies, as the photoelectric performance of the silicon solar cells is further enhanced and the price of the silicon is further reduced, the silicon solar cells will hold a significant position in photovoltaic field.

In an existing art, a solar cell module formed by cells generally includes a plurality of solar cell strings packaged by a packaging structure. The solar cell string includes a plurality of solar cells connected in series. The solar cell is provided with at least two busbars. When connected in series, two adjacent cells are electrically connected through a ribbon. The quantity of the ribbons is equal to the quantity of the busbars. Currently, the ribbons commonly used in the industry are flat bar-type ribbons. A ratio of a total width of the ribbons to a width of the solar cell is often greater than 3%. By taking a solar cell module having four busbars which is popular in the current market as an example, if the width of the cell is 156 mm, the width of the ribbon is 1.2 mm and a total width of the four ribbons is 4.8 mm, then the ratio of the total width of the ribbons to the width of the solar cells is 4.8/156=3.08%. To realize welding between the ribbons and the cell, a certain amount of silver paste must be consumed to print the busbars with a certain width on the cell. In addition, with using the ribbons with such width, the weight of the ribbons required by each module is large and the cost of the ribbons on each module is also high. Moreover, most of light irradiated on the ribbons cannot be absorbed and utilized by the solar cells due to the shielding of the ribbons, thereby reducing the photoelectric conversion efficiency of the solar cell module. However, if the width of the ribbon is decreased, the photoelectric conversion efficiency of the solar cell module is also reduced since the power loss caused by the resistance of the ribbon is greatly increased due to the decrease of cross sectional area of the ribbon. It is one of technological difficulties in the art to reduce the consumption of the silver paste on the cell and the power consumption of the ribbons of the solar cell module and also increase the photoelectric conversion efficiency of the solar cell module through ingenious design.

### SUMMARY

An aspect relates to providing a solar cell module.

To achieve the above aspect, a technical solution adopted by embodiments of the present invention is as follows: a solar cell module includes at least one solar cell string formed by a plurality of solar cells connected in series by conductive tapes.

The length L of the solar cell in the direction in which the plurality of solar cells are connected in series by the conductive tapes is less than or equal to 10 cm.

The ratio of the total width W of the conductive tapes adopted by each solar cell to the width D of the solar cell is 0.1% to 3%.

The ratio of the total width W of the conductive tapes to the length L of the solar cell is D: 8000 mm to D: 3000 mm.

The solar cell module includes multiple solar cell strings which are in a series structure or a series-parallel hybrid structure, i.e., first in series and then in parallel or first in parallel and then in series.

In the D: 8000 mm to D: 3000 mm, D refers to the width of the solar cell in unit of mm. The embodiments of the present invention have the characteristic that the solar cell with the length L less than or equal to 10 cm is adopted. The solar cell may be directly made of silicon wafers with a length less than or equal to 10 cm, may be a cell formed by cutting a normal entire cell through a slicing technology, and may also be a normal solar cell which is a remaining part in a process of removing defective parts from an entire solar cell having defectives through the slicing technology.

The ratio of the total width W of the conductive tapes to the length L of the corresponding solar cell is D: 8000 mm to D: 3000 mm. Here, “the corresponding solar cell” refers to the solar cell on which the conductive tapes are located, i.e., the ratio of the total width of the conductive tapes adopted by one solar cell to the length of the cell is D: 8000 mm to D: 3000 mm.

In an exemplary embodiment, the length of the solar cell in a direction in which the solar cells are connected in series by the conductive tapes is 0.5 to 10 cm.

In an exemplary embodiment, the length of the solar cell in a direction in which the solar cells are connected in series by the conductive tapes is 3 to 9 cm.

In the above technical solution, the ratio of the total width W of the conductive tapes adopted by each solar cell to the width D of the solar cell is 0.1% to 2%. Further, the ratio of the total width W of the conductive tapes adopted by each solar cell to the width D of the solar cell is 0.5% to 2%, and this ratio is an optimal design ratio, but the width of the conductive tape in such design may be narrow, thereby increasing difficulty of mass production.

In the above technical solution, the ratio of the total width W of the conductive tapes adopted by each solar cell to the width D of the solar cell is greater than 2% and less than 3%. Although the ratio does not reach the optimal design effect, it is easy to realize mass production.

In the above technical solution, the conductive tape refers to a metal tape that plays a conductive role. A shape of the metal tape may be a common flat shape, around, a bow, an oval or a polygon, or a flat strip with patterns on a single side or patterns on double sides, i.e., the shape of the metal tape is not limited.

In an embodiment of the above technical solution, a cross section of the conductive tape is a rectangle and a thickness of the conductive tape is 0.05 mm to 0.3 mm.

In another embodiment of the above technical solution, a cross section of the conductive tape is a circle or a bow and a diameter of the conductive tape is 0.1 mm to 0.4 mm.

Hereinbefore, the conductive tape is a metal tape coated with a metal or a metal alloy. The metal alloy coating is classified into three types: high-temperature welding alloy, low-temperature melting alloy and protection alloy.

The high-temperature welding alloy refers to metal or alloy which is melted at a conventional welding temperature and implements the electrical connection through welding, such as tin-lead alloy, tin-silver alloy and the like.

The low-temperature melting alloy refers to metal or alloy which is melted at a temperature of 100° C. to 200° C. and implements the electrical connection, such as indium-tin alloy and the like which is melted at a laminating temperature and is electrically connected with the cell and the conductive tape.

The protection alloy refers to metal or alloy that only plays a protection role on the conductive tape, and the electrical connection cannot be implemented through the protection layer, such as silver alloy or other protection layers that protect the metal tape from oxidation corrosion.

The classification of the above alloy coating is not limited to this. For example, the tin-lead alloy can be classified into high-temperature welding alloy or protection alloy according to the thicknesses of the tin-lead alloy. The tin-lead alloy which can reach a welding thickness belongs to the high-temperature welding alloy, while the tin-lead alloy which cannot reach the welding thickness belongs to the protection alloy.

Of course, the conductive tape may also be a metal tape without a metal alloy coating.

The solar cells are solar cells with busbars, and the quantity of the busbars on the solar cell is 2-20.

In the above technical solution, the solar cell is formed by cutting an entire solar cell.

In an embodiment of the above technical solution, the solar cell is a half of the entire solar cell formed by cutting the entire solar cell according to a slicing ratio of ½. By taking a conventional cell of 156×156 mm as an example, the solar cells of 156×78 mm are obtained according to the slicing ratio of ½.

In a second embodiment of the above technical solution, the solar cell is ⅓ of the entire solar cell formed by cutting the entire solar cell according to a slicing ratio of ⅓.

In a third embodiment of the above technical solution, the solar cell is ¼ of the entire solar cell formed by cutting the entire solar cell according to a slicing ratio of ¼. An existing conventional solar cell is generally 156×156 mm. After slicing, solar cells with a length less than or equal to 10 cm can be obtained, and still have a width of 156 mm.

In an exemplary embodiment, widths of the conductive tapes adopted by the solar cells are equal.

In the above technical solution, the cells with busbars and the conductive tapes are adopted. The conductive tape herein may be a metal tape coated with a high-temperature welding alloy, such as a ribbon in which copper base material is coated with tin-lead alloy, and the conductive tape implements the electrical connection through welding or a conductive adhesive. The conductive tape may also be the above metal tape with or without protection alloy coating, which is electrically connected with the cell through the conductive adhesive.

In another technical solution, a solar cell module includes at least one solar cell string formed by a plurality of solar cells connected in series by conductive tapes.

The solar cells are solar cells without busbars, and a length L of the solar cell in a direction in which the plurality of solar cells are connected in series by the conductive tapes is less than or equal to 10 cm.

A ratio of a total width W of the conductive tapes adopted by each solar cell to a width D of the solar cell is 0.1% to 3%.

A ratio of the total width W of the conductive tapes to the length L of the corresponding solar cell is D: 8000 mm to D: 3000 mm.

In the above technical solution, the conductive tape is a metal tape coated with metal coating or metal alloy.

In the above technical solution, the solar cell without busbar and the metal tape with a coating are adopted. For example, the solar cell without busbar and the metal tape with a high-temperature welding alloy coating or protection alloy coating are adopted and the solar cell and the metal tape are electrically connected through the conductive adhesive. For another example, the solar cell without busbar and the metal tape with a low-temperature melting alloy coating are adopted, and the solar cell and the metal tape are electrically connected by the melting of the alloy at laminating temperature.

The principle of embodiments of the present invention is described below. The resistance power loss of the conductive tape of the solar cell module is A*A*B(ρ/h)*Jₘₚ/(m*Vₘₚ*W_{B}), where A is the length of the solar cell; B is half of a spacing between two busbars; ρ is a bulk resistivity of the conductive tape; h is the thickness of the conductive tape; Jₘₚ is a current density of a maximum working point; m is a constant; Vₘₚ is a voltage in a solar cell unit at the maximum working point; and W_{B} is half of the width of the conductive tape. The shading power loss of the conductive tape of the solar cell module is n*W_{B}/B, where n is a constant that represents reflectivity in the conductive tape. The optimal width of the conductive tape shall satisfy: a derivative is taken with respect to W_{B} by a sum of the resistance power loss and the shading power loss of the conductive tape is equal to 0. Through derivation, for a flat conductive tape with a rectangular or approximately rectangular cross section, the optimal W_{B}=A*B(ρ*Jₘₚ/(h*m*n*Vₘₚ))^{1/2} is. For a circular or approximately circular conductive tape, an optimal diameter (i.e., an optimal width) W_{B}=(4A²*B²*ρ*Jₘₚ/(3π*m*n*Vₘₚ))^{1/3}. Therefore, W_{B}/B has a positive correlation with A, i.e., a ratio of the total width W of the conductive tapes adopted by each solar cell to the width D of the solar cell has a positive correlation with the length of the solar cell.

Since the above technical solution is applied, compared with an existing art, embodiments of the present invention has the following advantages:

1. The present disclosure designs a new solar cell module, further designs a conductive tape with reasonable width by using solar cells with the length less than or equal to 10 cm, and proposes the ratio of the total width of the conductive tapes to the length of the solar cell. The present disclosure perfectly harmonizes a contradiction between the shading loss and the resistance loss of the conductive tape, and realizes maximization of output power. It is proved by experiments that compared with an existing art in which an entire solar cell is used, on a premise of adopting the same amount of the silicon wafers, the shading loss and the resistance loss are greatly reduced and the output power of the module is greatly increased; and an unexpected technical effect is obtained;

2. With embodiments of the present invention, the amount of paste and the conductive tapes are saved, the cost is reduced. Therefore, embodiments of the present invention has positive practical significance.

3. The embodiments of the present invention is well compatible with the existing technology, and is easy in preparation, low in cost and is worthy of promotion and application.

4. In embodiments of the present invention, a configuration of solar cells without busbars and the metal tape with the coating may be used, so that the shading loss and the resistance loss are greatly reduced, the output power of the module is greatly increased, and moreover the conductive tape consumption and the conductive adhesive consumption are reduced remarkably, thereby achieving an unexpected technical effect.

### BRIEF DESCRIPTION

Some of the embodiments will be described in detail, with reference to the following figures, wherein like designations denote like members, wherein:

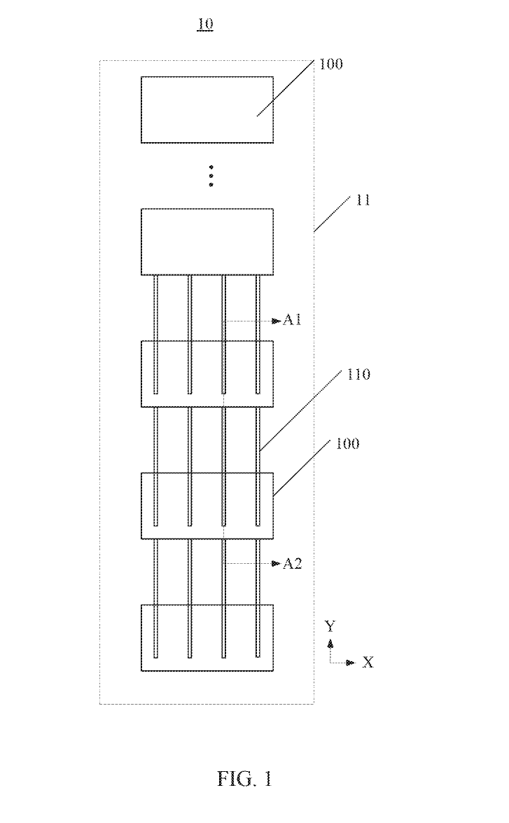

FIG. 1 is a schematic diagram of a solar cell module according to embodiment 1 of the present disclosure;

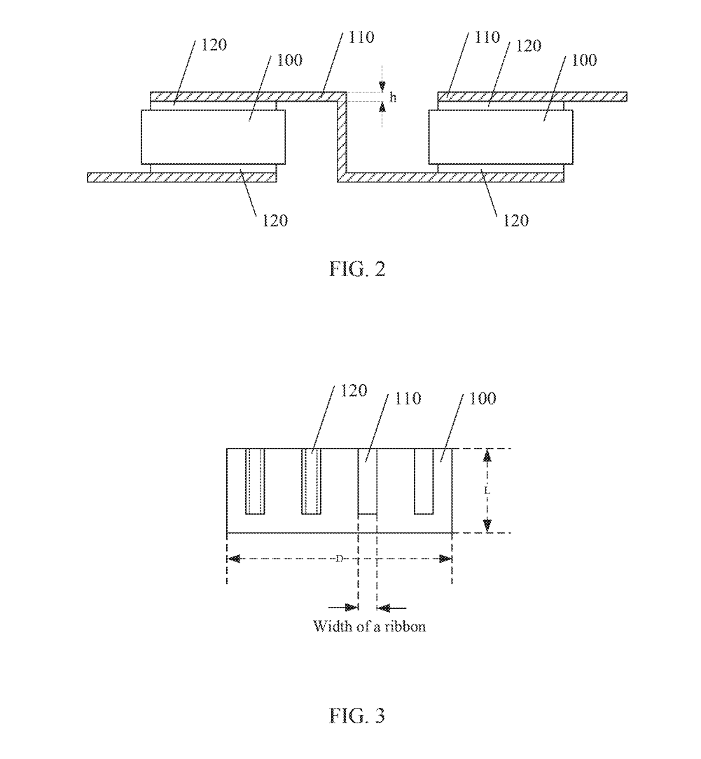

FIG. 2 is a schematic sectional view of the solar cell module taken along line A1A2 shown in FIG. 1;

FIG. 3 is a schematic diagram of a solar cell according to the present disclosure;

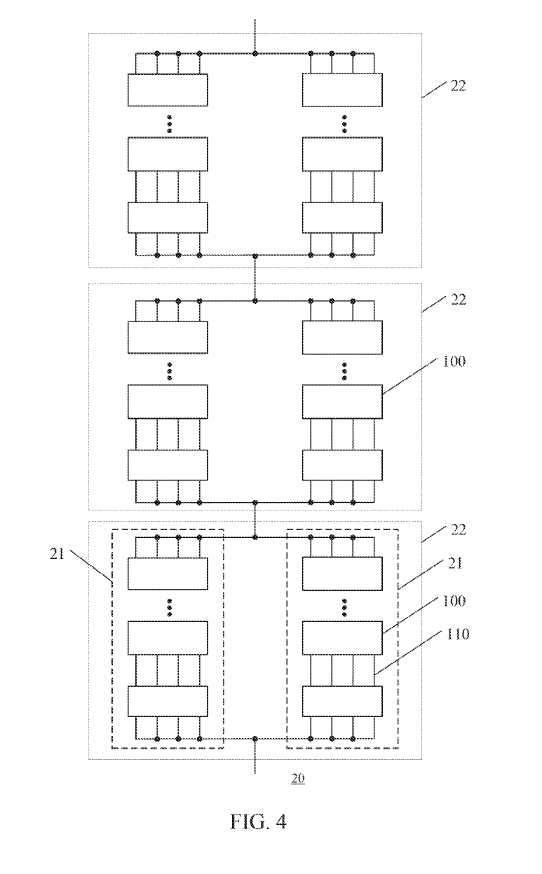

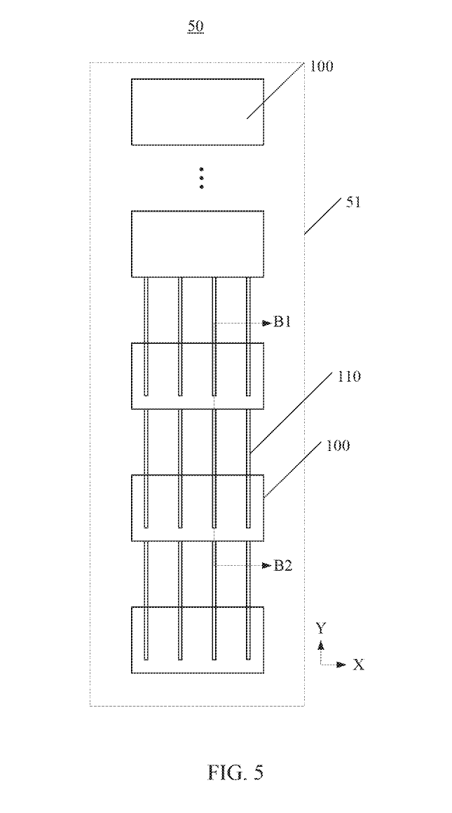

FIG. 4 is a schematic diagram of a solar cell module according to embodiment 2 of the present disclosure;

FIG. 5 is a schematic diagram of a solar cell module according to embodiment 5 of the present disclosure; and

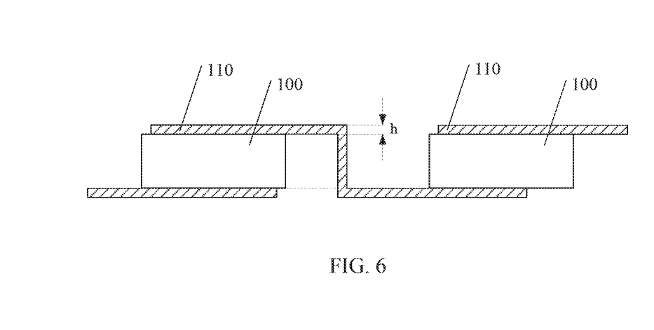

FIG. 6 is a schematic sectional view of the solar cell module taken along line B1B2 shown in FIG. 5.

### DETAILED DESCRIPTION

The present disclosure is further described below in conjunction with embodiments.

### Embodiment 1

A solar cell module 10 includes one solar cell string 11 having 120 solar cells 100 connected in series by ribbons 110.

The solar cells 100 in the solar cell string 11 have the same size, and each of the solar cells 100 is half (i.e., 156×78 mm) of an entire solar cell (156×156 mm) formed by cutting the entire solar cell according to a slicing ratio of ½. Each solar cell is provided with four busbars 120 each having a width of 0.5 mm, and a total width of the four busbars 120 accounts for 1.28% of a width of the solar cell.

Each solar cell 100 is provided with four ribbons 110. A width of each of the four ribbons is 0.6 mm, and a thickness h of each of the four ribbons is 0.2 mm. A total width W of the ribbons covered on each solar cell is 2.4 mm, the total width W accounts for 1.54% of the width of the solar cell; and W/D=L/5070 mm.

### Embodiment 2

A solar cell module 20 includes six solar cell strings 21 each having 20 solar cells 100 connected in series by ribbons 110. Every two solar cell strings form a parallel unit 22, so there are three parallel units 22. The three parallel units 22 are connected in series.

Each solar cell in the solar cell strings has the same size, which is half (i.e., 156×78 mm) of an entire solar cell (156×156 mm) formed by cutting the entire solar cell according to a slicing ratio of ½. Each solar cell is provided with four busbars each having a width of 0.8 mm and a thickness h of 0.15 mm. A total width W of ribbons covered on each solar cell is 3.2 mm, a ratio of W to the width of the solar cell is 2.05%; and W/D=L/3803 mm.

### Embodiment 3

A solar cell module includes one solar cell string having 240 solar cells connected in series by ribbons.

Each solar cell in the solar cell string has the same size, which is a quarter of an entire solar cell (156×156 mm) formed by cutting the entire solar cell according to a slicing ratio of ¼, that is, each solar cell is 156×39 mm. Each solar cell is provided with four busbars. A width of each of the four busbars is 0.2 mm; and a ratio of a total width of the busbars to a width of the solar cell is 1.28%.

Each solar cell is provided with four strip-shaped ribbons. A width of each of the four ribbons is 0.3 mm, and a thickness his 0.2 mm. A total width W of the ribbons covered on each solar cell is 1.2 mm; a ratio of the total width W to the width of the solar cell is 0.77%; and W/D=L/5070 mm.

### Embodiment 4

A solar cell module includes one solar cell string formed by 240 solar cells which are connected in series by ribbons.

Each solar cell in the solar cell string has the same size. Each solar cell is formed by cutting an entire solar cell (156×156 mm) according to a slicing ratio of ¼, that is, the size of each solar cell is 156×39 mm. Each solar cell is provided with six busbars. A width of each of the six busbars is 0.2 mm, and a ratio of a total width of the busbars to a width of the solar cell is 0.77%.

Each solar cell is provided with six circular ribbons. A diameter of each of the six ribbons is 0.28 mm, a total width W of the ribbons covered on each solar cell is 1.68 mm; a ratio of the total width W to the width of the solar cell is 1.08%; and W/D=L/3621 mm.

### Embodiment 5

A solar cell module 50 includes one solar cell string 51 formed by 120 solar cells 100 which are connected in series by conductive tapes 110.

Each solar cell 100 in the solar cell string 51 has the same size. Each solar cell is formed by cutting an entire solar cell (156×156 mm) according to a slicing ratio of ½. That is, the size of each solar cell is 156×78 mm.

The solar cell 100 is provided without busbar. Two solar cells are connected with each other by means of four conductive tapes 110. A width of the conductive tape is 0.8 mm, and a thickness h is 0.15 mm. A surface of the conductive tape is coated with silver, and the conductive tapes and the solar cell are electrically connected via conductive adhesives.

A total width W of the conductive tapes covered on each solar cell is 3.2 mm; a ratio of the total width W to the width of the solar cell is 2.05%; and W/D=L/3803 mm.

### Reference Example 1

A solar cell module includes one solar cell string formed by 60 solar cells which are connected in series by ribbons.

The solar cells in the solar cell string have a same size, and an entire solar cell (156×156 mm) is adopted for each solar cell.

Each solar cell is provided with four busbars each having a width of 1.1 mm.

Each solar cell is provided with four ribbons. A width of each of the four ribbons is 1.2 mm, and a thickness his 0.2 mm. A ratio of a total width W of the ribbons covered on each solar cell to the width of the solar cell is 3.08%.

A ratio of the total width W of the ribbons to a length L of the corresponding solar cell is 1:32.5.

### Reference Example 2

A solar cell module includes one solar cell string formed by 60 solar cell connected in series by conductive tapes.

The solar cells in the solar cell string have a same size, and an entire solar cell (156×156 mm) is adopted for each solar cell.

Each solar cell is not provided with busbars, and two solar cells are connected with each other by means of four conductive tapes. A width of each of the conductive tapes is 1.2 mm, and a thickness h is 0.2 mm. A surface of each conductive tape is coated with silver, and the conductive tapes and the cells are electrically connected via conductive adhesives.

A total width W of the conductive tapes is 4.8 mm, a ratio of the total width W to the width of the solar cell is 3.08%; and a ratio of the total width W of the ribbons covered on each solar cell to a length L of the corresponding solar cell is 1:32.5.

Tests of the shading loss, the resistance loss and the output power, and electrical performance tests are made to above embodiments and reference examples. Comparison is made as follows:

| | Width of | | | | |
|---|---|---|---|---|---|
| | conductive tape | Pmax | Voc | Isc | FF |
| Embodiment 1 | 0.6 mm | 267.9 | 75.72 | 4.56 | 77.60% |
| Embodiment 2 | 0.8 mm | 265.8 | 37.86 | 9.05 | 77.59% |
| Embodiment 3 | 0.3 mm | 271.7 | 151.44 | 2.30 | 78% |
| Embodiment 4 | 0.28 mm | 274.6 | 151.45 | 2.31 | 78.50% |
| Reference | 1.2 mm | 260.1 | 37.77 | 8.97 | 76.76% |
| example 1 | | | | | |
| Embodiment 5 | 0.8 mm | 266 | 37.88 | 9.05 | 77.59% |
| Reference | 1.2 mm | 260.5 | 37.84 | 8.97 | 76.76% |
| example 2 | | | | | |

It can be seen from the above table that compared with the existing entire solar cell (reference example 1), on a premise of using the same amount of the silicon wafers, the width of the busbar of the cell is greatly reduced, the consumption of silver paste is greatly decreased, and the consumption of the conductive adhesive is greatly reduced, but the power of the module is still increased greatly.

Thus, the shading loss and the resistance loss of the present disclosure are greatly reduced and the output power of the module is greatly increased; and an unexpected technical effect is obtained. Meanwhile, since narrower and thinner conductive tapes are used in the present disclosure, the consumption of the conductive tapes of the module is greatly decreased, thereby saving cost. Meanwhile, since narrower and thinner conductive tapes are used in the present disclosure, the width of the busbar of the corresponding cell is also narrowed, thereby decreasing consumption of paste for a front surface printing and consumption of paste for a back electrode of the cell and also saving the cost. Meanwhile, an area of an aluminum back surface field of the corresponding cell is increased, which is favorable for further increasing power output of the module.

It can be learned from comparison between embodiment 5 and reference example 2 that: the shading loss and the resistance loss of embodiment 5 are greatly reduced and the output power of the module is greatly increased. Meanwhile, since the width of the conductive tape is decreased, the consumption of the conductive tapes is greatly decreased. Since the cells without the busbars are provided with expensive silver-coated conductive tapes, embodiment 5 greatly reduces the cost of the conductive tapes. In addition, since the width of the conductive tape is decreased, the amount of the conductive adhesives demanded for connecting the cells and the conductive tapes is decreased accordingly, thereby further reducing the production cost.

Although the present invention has been disclosed in the form of preferred embodiments and variations thereon, it will be understood that numerous additional modifications and variations could be made thereto without departing from the scope of the invention.

For the sake of clarity, it is to be understood that the use of ‘a’ or ‘an’ throughout this application does not exclude a plurality, and ‘comprising’ does not exclude other steps or elements.

What is claimed is:

1. A solar cell module, comprising:
at least one solar cell string, each solar cell string of which comprises a plurality of solar cells connected in series by conductive tapes;
wherein each solar cell is provided with at least two busbars, and a length of the solar cell in a busbar direction is less than or equal to 10 cm;
wherein a ratio of a total width of the conductive tapes adopted by the solar cell to a width of the solar cell is 0.1% to 3%; and
wherein a ratio of the total width of the conductive tapes adopted by the solar cell to the length of the solar cell is: 8000 mm to 3000 mm.

2. The solar cell module according to claim 1, wherein the length of the solar cell in the busbar direction is 3 cm-9 cm.

3. The solar cell module according to claim 1, wherein each solar cell is provided with 2-20 busbars.

4. The solar cell module according to claim 1, wherein the solar cell is formed by cutting an entire solar cell.

5. The solar cell module according to claim 4, wherein each of the solar cells is a half of the entire solar cell formed by cutting the entire solar cell according to a slicing ratio of ½.

6. The solar cell module according to claim 1, wherein a quantity of the conductive tapes adopted by each solar cell is the same as a quantity of the busbars thereof.

7. The solar cell module according to claim 1, wherein each conductive tape adopted by the solar cell has a same width.

8. The solar cell module according to claim 1, wherein a ratio of a total width of the busbars for each solar cell to the width of the solar cell is 0.1% to 2%.

9. A solar cell module, comprising:
at least one solar cell string, each solar cell string of which comprises a plurality of solar cells connected in series by conductive tapes, wherein:
each solar cell is provided without busbar, and a length of the solar cell in a direction in which the plurality of solar cells are connected in series by the conductive tapes is less than or equal to 10 cm;
a ratio of a total width of the conductive tapes adopted by the solar cell to a width of the solar cell is 0.1% to 3%; and
a ratio of the total width of the conductive tapes to the length of the solar cell is 8000 mm to 3000 mm.

10. The solar cell module according to claim 9, wherein each conductive tape is a metal tape coated with metal or metal alloy.

11. A solar cell module, comprising:
at least one solar cell string each comprising a plurality of solar cells connected in series in a first direction;
wherein each of the plurality of solar cells has a length (L) in the first direction and a width (D) in a second direction substantially perpendicular to the first direction, every two adjacent solar cells are electrically connected by two or more conductive tapes having a total width (W),
wherein the length (L) is less than or equal to 10 cm, 0.1%≤W/D≤3%, and
$$\frac{D}{8000 mm} \leq W / L \leq \frac{D}{3000 mm} .$$

12. The solar cell module according to claim 11, wherein the length (L) of each of the plurality of solar cells is 3 cm-9 cm.

13. The solar cell module according to claim 11, wherein the two or more conductive tapes have a same width.

14. The solar cell module according to claim 11, wherein each of the plurality of solar cells is provided with at least two busbars extending in the first direction.

15. The solar cell module according to claim 14, wherein each of the plurality of solar cells is provided with 2-20 busbars.

16. The solar cell module according to claim 14, wherein a quantity of the two or more conductive tapes between two adjacent solar cells is equal to a quantity of the at least two busbars of each of the plurality of solar cells.

17. The solar cell module according to claim 14, wherein a ratio of a total width of the at least two busbars adopted by each of the plurality of solar cells to the width (D) of the each of the plurality of solar cells is 0.1% to 2%.
